(19) United States
(12) Patent Application Publication
(10) Pub. No.: US 2005/0089766 A1
(43) Pub. Date: Apr. 28, 2005

(54) Method for improving uniformity and alignment accuracy of contact hole array pattern

(75) Inventors: Soung Su Woo, Gyeonggi-do (KR); Se Young Oh, Seoul (KR)

Correspondence Address: HELLER EHRMAN WHITE & MCAULIFFE LLP, 1717 RHODE ISLAND AVE, NQ, WASHINGTON, DC, 20036-3001, US

(73) Assignee: Hynix Semiconductor Inc., Gyeonggi-do (KR)

(21) Appl. No.: 10/879,571

(22) Filed: Jun. 29, 2004

(30) Foreign Application Priority Data
Oct. 23, 2003 (KR) 2003-0074172

(51) Int. Cl. H01L 21/4763; G03C 5/00; G03F 9/00

(52) U.S. Cl. 430/5; 430/311

(57) ABSTRACT

The present invention discloses a method for improving uniformity and alignment accuracy of contact hole array pattern. A dummy mask pattern is added to adjacent to contact hole array mask pattern during a design of an exposure mask to maintain a uniformity of contact hole size and prevent contact hole size error and shift of the contact hole pattern.

### BACKGROUND OF THE INVENTION

1. Field of the Invention

The present invention relates to method for improving uniformity and alignment accuracy of contact hole array pattern, and in particular to method for improving uniformity and alignment accuracy of contact hole array pattern wherein a dummy mask pattern is added to adjacent to contact hole array mask pattern during a design of an exposure mask to maintain a uniformity of contact hole size and prevent contact hole size error and shift of the contact hole pattern.

2. Description of the Background Art

FIG. 1A is a plane view of a conventional exposure mask including a contact hole array mask pattern and FIG. 1B is a plane view of a contact hole array pattern formed via a photolithography process using the exposure mask of FIG. 1A.

Referring to FIGS. 1A and 1B, when an exposure and development process performed using an exposure mask 10 including a contact hole array mask pattern 20-1 and an edge contact hole mask pattern 30-1 having the same size, an edge contact hole pattern 30-2 having a size smaller than that of contact hole array mask pattern 20-2 is formed in a photoresist film. That is, as shown in FIG. 1A, contact holes are designed to have the same size and shape. However, the size of the edge contact hole 30-2 is reduced. Moreover, in worst case, the edge contact hole is not open. Sizes of contact hole patterns in the contact hole array pattern adjacent to the edge contact hole pattern are also reduced.

In order to solve above-described problems, a method illustrated in FIGS. 2A and 2B have been proposed.

FIG. 2A is a plane view of an exposure mask manufactured by utilizing a conventional edge pattern correction method and FIG. 2B is a plane view of a contact hole array pattern formed via a photolithography process using the exposure mask of FIG. 2A.

Referring to FIGS. 2A and 2B, taking the shrinkage of the edge contact hole pattern into consideration during a designing process of mask pattern, an exposure mask 40 is designed to have an edge contact hole mask pattern 60-1 having a size larger than that of a contact hole array hole mask pattern 50-1. This method may prevent shrinkage of contact holes. However, a size of an edge contact hole pattern 60-2 may be larger than that of a contact hole array hole mask pattern 50-1. Moreover, when errors such as mean to target error, transmittance error and phase error occurs, the size and the position of the edge contact hole pattern may be unpredictably changed.

### SUMMARY OF THE INVENTION

Accordingly, it is an object of the present invention to provide method for correcting edge contact hole pattern wherein a dummy mask pattern is added to adjacent to contact hole array mask pattern during a design of an exposure mask to maintain a uniformity of contact hole size and prevent contact hole size error and shift of the contact hole pattern.

In order to achieve the above-described object of the invention, there is provided a method for correcting edge contact hole pattern, characterized in that a dummy mask pattern is formed adjacent to an edge contact hole mask pattern of a contact hole array mask pattern on a exposure mask.

### BRIEF DESCRIPTION OF THE DRAWINGS

The present invention will become better understood with reference to the accompanying drawings which are given only by way of illustration and thus are not limitative of the present invention, wherein:

FIG. 1A is a plane view of a conventional exposure mask including a contact hole array mask pattern.

FIG. 1B is a plane view of a contact hole array pattern formed via a photolithography process using the exposure mask of FIG. 1A.

FIG. 2A is a plane view of an exposure mask manufactured by utilizing a conventional edge pattern correction method.

FIG. 2B is a plane view of a contact hole array pattern formed via a photolithography process using the exposure mask of FIG. 2A.

FIG. 3A is a plane view of an exposure mask manufactured by utilizing an edge pattern correction method of the present invention.

FIG. 3B is a plane view of a contact hole array pattern formed via a photolithography process using the exposure mask of FIG. 3A.

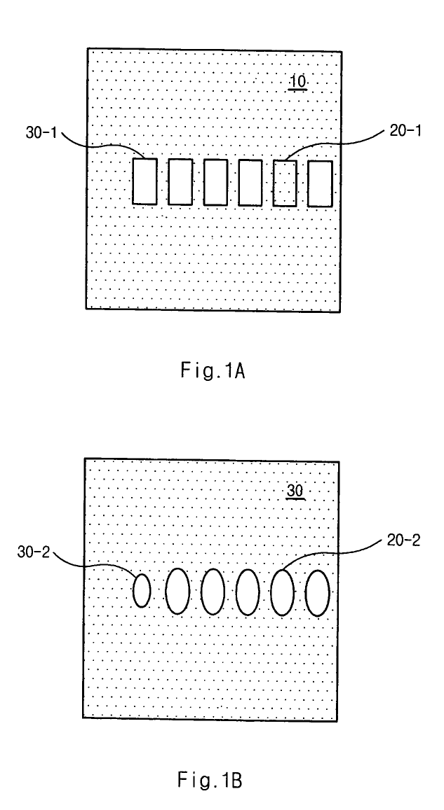

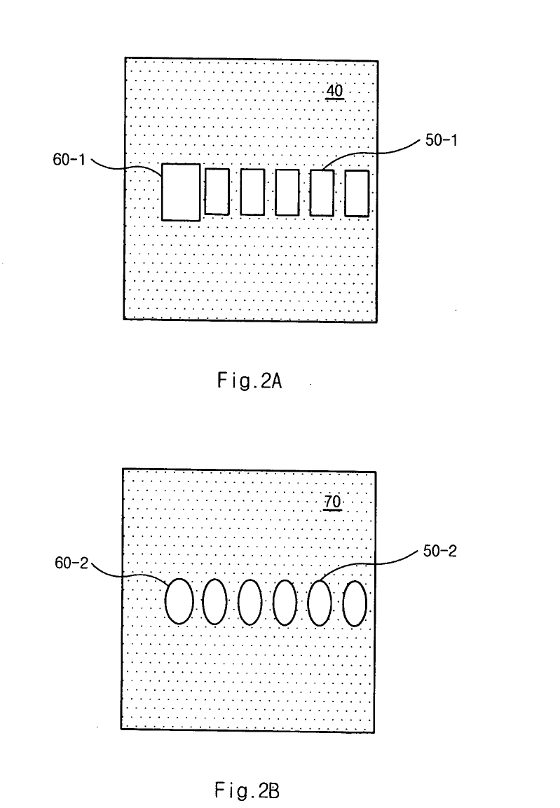

### DETAILED DESCRIPTION OF THE PREFERRED EMBODIMENTS

A method for correcting edge contact hole pattern in accordance with a preferred embodiment of the present invention will now be described in detail with reference to the accompanying drawings.

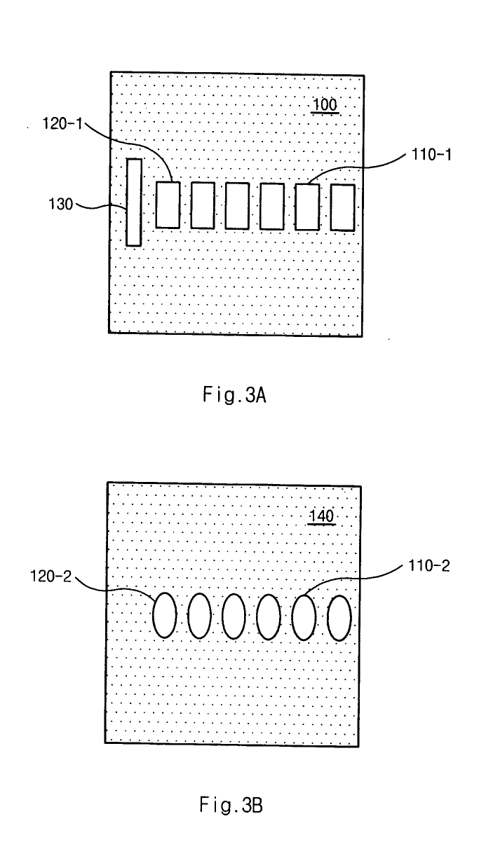

FIGS. 3A is a plane view of an exposure mask manufactured by utilizing an edge pattern correction method of the present invention.

Referring to FIG. 3A, a plurality of square contact hole mask pattern, i.e. a contact hole array mask pattern 110-1, is disposed on an exposure mask 100. A dummy mask pattern 130 is additionally disposed on the exposure mask 100 adjacent to the last contact hole mask pattern of the array mask pattern 110-1, i.e. an edge contact hole pattern 120-1. That is, during a designing process of mask pattern layout, a dummy mask pattern 130 is added to the array mask pattern 110-1 and then the exposure mask 100 is manufactured. The dummy mask pattern refers to a sufficiently small pattern so as not to be transcribed onto a photoresist film although the pattern is on the exposure mask. For example, a slit pattern having a width less than the minimum line width can be used as a dummy pattern. Exemplary dimensions of the contact hole mask pattern and the dummy patterns are as follows. When the contact hole mask pattern has a size of 140 nm×280 nm and is spaced apart from each other by 70 nm, the dummy mask pattern may have a size of 100 nm×560 nm and is spaced apart from the edge contact hole mask pattern by 120 nm.

FIG. 3B is a plane view of a contact hole array pattern formed via a photolithography process using the exposure mask of FIG. 3A.

Referring to FIG. 3B, a plurality of contact hole patterns, i.e. a contact hole array pattern 110-2 is formed on a photoresist film 140 by an exposure and development process. An edge contact hole pattern 120-2 has a size substantially same to that of other contact holes in the contact hole array pattern 110-2.

Although not shown, a plurality of dummy mask patterns may be formed on the exposure mask.

As discussed earlier, in accordance with the present invention, a dummy mask pattern is added to adjacent to contact hole array mask pattern during a design of an exposure mask to maintain a uniformity of contact hole size and prevent contact hole size error and shift of the contact hole pattern.

As the present invention may be embodied in several forms without departing from the spirit or essential characteristics thereof, it should also be understood that the above-described embodiment is not limited by any of the details of the foregoing description, unless otherwise specified, but rather should be construed broadly within its spirit and scope as defined in the appended claims, and therefore all changes and modifications that fall within the metes and bounds of the claims, or equivalences of such metes and bounds are therefore intended to be embraced by the appended claims.

1. A method for correcting edge contact hole pattern, characterized in that a dummy mask pattern is formed adjacent to an edge contact hole mask pattern of a contact hole array mask pattern on a exposure mask.
